(19) United States
(12) Patent Application Publication
(10) Pub. No.: US 2010/0055868 A1
(43) Pub. Date: Mar. 4, 2010

(54) Method of forming insulation layer of semiconductor device and method of forming semiconductor device using the insulation layer

(76) Inventors: Mi-young Lee, Seoul (KR); Min-young Park, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/461,096

(22) Filed: Jul. 31, 2009

(30) Foreign Application Priority Data
Sep. 2, 2008 (KR) 10-2008-0086289

(51) Int. Cl. H01L 21/762; H01L 21/312; H01L 21/316

(52) U.S. Cl. 438/435; 438/763; 257/E21.26; 257/E21.278; 257/E21.546

(57) ABSTRACT

A method of forming an insulating layer of a semiconductor device, the method including preparing a semiconductor substrate having a plurality of structures and gaps between adjacent structures, forming an insulating layer for oxygen supply on the semiconductor substrate, forming an SOG (spin-on-glass) layer on the insulating layer for oxygen supply to fill the gaps, and curing the SOG layer, wherein the insulating layer for oxygen supply supplies oxygen to the SOG layer during curing of the SOG layer.

### BACKGROUND

1. Field

Embodiments relate to a method of forming a semiconductor device and, more particularly, to a method of forming an insulating layer of a semiconductor device and a method of forming a semiconductor device using the insulating layer.

2. Description of the Related Art

It is necessary to reduce a design rule of a semiconductor device to increase the integration degree of the semiconductor device. As the design rule is reduced, the gap-filling capability of a device isolation layer or an interlayer dielectric layer becomes very important. Using a high-density plasma (HDP) oxide layer to fill a narrow gap or a trench is limited because voids are created. Thus, much attention has been given to a use of a spin-on-glass (SOG) layer to fill a narrow gap or a trench. The SOG layer is obtained by sequentially performing spin coating and a curing operation, in which the SOG layer is coated in a liquid or sol state. The SOG layer has a good gap-filling capability and is readily available for reducing a step since the SOG layer is coated in a liquid or sol state.

### SUMMARY

Embodiments are therefore directed to a method of forming an insulation layer of a semiconductor device and a method of forming a semiconductor device using the insulation layer, which substantially overcome one or more of the problems due to the limitations and disadvantages of the related art.

It is therefore a feature of an embodiment to provide a method of evenly forming a spin-on-glass (SOG) oxide layer by preventing curing failures from occurring in an SOG layer filling a narrow gap or a trench, and a method of forming a semiconductor device using such an SOG oxide layer.

At least one of the above and other features and advantages may be realized by providing a method of forming an insulating layer of a semiconductor device, the method including, preparing a semiconductor substrate having a plurality of structures and gaps between adjacent structures, forming an insulating layer for oxygen supply on the semiconductor substrate, forming an SOG (spin-on-glass) layer on the insulating layer for oxygen supply to fill the gaps, and curing the SOG layer, wherein the insulating layer for oxygen supply supplies oxygen to the SOG layer during curing of the SOG layer.

The SOG layer may be directly on the insulating layer for oxygen supply.

The insulating layer for oxygen supply may include an OH-rich silicon oxide layer.

The OH-rich silicon oxide layer may be formed through atomic layer deposition (ALD) or chemical vapor deposition (CVD) using H₂O vapor.

The OH-rich silicon oxide layer may be formed at about 100° C. to about 300° C.

The SOG layer may be formed of a polysilazane-based material.

The method may further include baking the SOG layer after forming the SOG layer and before curing the SOG layer.

Curing the SOG layer may include annealing under an atmosphere of H₂O or under an atmosphere that does not contain an oxygen supply gas.

The structures may include conductive lines.

The plurality of structures and the gaps may be formed on an active area of the semiconductor substrate, and the gaps may include trenches in which a device isolation layer is to be formed.

At least one of the above and other features and advantages may also be realized by providing a method of forming a semiconductor device, the method including forming a plurality of trenches in a semiconductor substrate, forming an insulating layer for oxygen supply on the semiconductor substrate including the trenches, forming an SOG (spin-on-glass) layer on the insulating layer for oxygen supply on the semiconductor substrate to fill the trenches with the SOG layer, and curing the SOG layer, wherein the insulating layer for oxygen supply supplies oxygen to the SOG layer during curing of the SOG layer.

The insulating layer for oxygen supply may include an OH-rich silicon oxide layer formed using H₂O vapor.

The SOG layer may be directly on the insulating layer for oxygen supply.

The method may further include planarizing the cured SOG layer to form a device isolation layer.

At least one of the above and other features and advantages may also be realized by providing a method of forming a semiconductor device, the method including forming a plurality of trenches in a semiconductor substrate, forming an insulating layer for oxygen supply on the semiconductor substrate including the trenches, forming an SOG (spin-on-glass) layer on the insulating layer for oxygen supply on the semiconductor substrate to fill the trenches with the SOG layer, recessing parts of the SOG layer in the trenches, curing the SOG layer on the semiconductor substrate, and forming an upper insulating layer on the SOG layer to fill the trenches, wherein the insulating layer for oxygen supply supplies oxygen to the SOG layer during curing of the SOG layer.

The insulating layer for oxygen supply may include an OH-rich silicon oxide layer formed using H₂O vapor.

The SOG layer may be directly on the insulating layer oxygen supply.

The upper insulating layer may include one of a HDP (high-density plasma) silicon oxide layer and an O₃-TEOS silicon oxide layer.

The method may further include planarizing the cured SOG layer to form a device isolation layer.

The method may further include forming gate insulating layers and gate electrodes on the semiconductor substrate.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a flowchart showing a method of forming an insulating layer of a semiconductor device according to an embodiment;

FIG. 2 illustrates H₂O escaping from a silicon oxide layer containing many hydroxyl (OH) groups;

FIG. 3 illustrates FT-IR spectra of an OH-rich silicon oxide layer;

FIGS. 4A through 4C illustrate FT-IR spectra of a spin-on-glass (SOG) layer;

FIGS. 5A through 5C illustrate FT-IR spectra of an SOG layer deposited on an OH-rich silicon oxide layer;

FIGS. 6A through 6F illustrate cross-sectional views of stages in a method of forming a semiconductor device according to an embodiment;

FIGS. 7A through 7C illustrate cross-sectional views of stages in a method of forming a semiconductor device according to another embodiment; and

FIGS. 8A through 8E illustrate cross-sectional views of stages in a method of forming a semiconductor device according to another embodiment.

### DETAILED DESCRIPTION

Korean Patent Application No. 10-2008-0086289, filed on Sep. 2, 2008, in the Korean Intellectual Property Office, and entitled, “Method of Forming Insulation Layer of Semiconductor Device and Method of Forming Semiconductor Device Using the Insulation Layer,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

In the present detailed description, a spin-on-glass (SOG) layer is obtained by applying an SOG solution to a layer on which a curing operation is not performed. The SOG layer is a layer that is formed of a bond of silicon, nitrogen and hydrogen that has not yet to be changed into a silicon oxide layer. Also, in the present detailed description, an SOG oxide layer is a silicon oxide layer obtained by oxidizing the SOG layer through curing. In some cases, the SOG layer may include the SOG oxide layer.

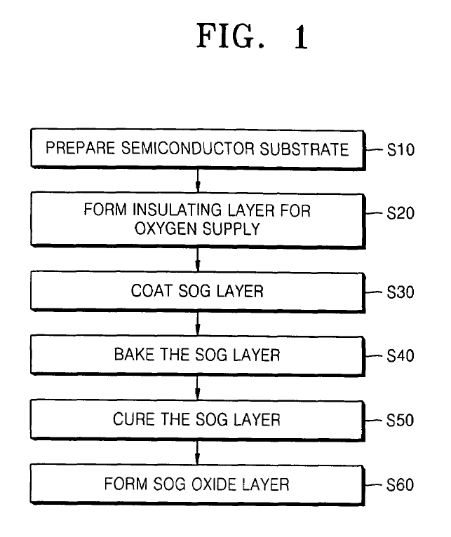

FIG. 1 illustrates a flowchart showing a method of forming an insulating layer of a semiconductor device according to an embodiment. First, a semiconductor substrate may be prepared (operation S10). Structures, e.g., gate electrodes or metal interconnections, may be formed on the semiconductor substrate, and gaps may be formed between the structures. Alternatively, trenches may be formed on the semiconductor substrate.

Then, an insulating layer, e.g., an OH-rich silicon oxide layer, may be formed on the semiconductor substrate having the gaps between structures or the trenches to supply oxygen (operation S20). The OH-rich silicon oxide layer may have less Si—O bonds and more Si—OH bonds than a general silicon oxide layer.

The OH-rich silicon oxide layer may be formed using atomic layer deposition (ALD), plasma-enhanced chemical vapor deposition (PECVD) or a high-density plasma (HDP) method. For example, hexachloro disilane (HCD) (Si₂Cl₆) or silicon tetrachloride (SiCl₄) may be used as a silicon source for forming the OH-rich silicon oxide layer. H₂O vapor may be used as a source of the OH groups. The OH-rich silicon oxide layer may be obtained according to a low-temperature process. The OH-rich silicon oxide layer may be obtained by performing a process at about 100° C. to about 300° C., particularly, at about 100° C. Since H₂O vapor is hardly generated at a temperature below 100° C., it may be difficult to obtain the OH-rich silicon oxide layer at a temperature below 100° C. Since Si—O bonds of a silicon oxide layer become dense at a temperature above 300° C., it may be difficult to form the silicon oxide layer to contain many OH groups at a temperature above 300° C. That is, the OH-rich silicon oxide layer may be obtained by performing a process at about 100° C. to about 300° C. because, in that temperature range, Si—O bonds of a silicon oxide layer are not densely formed and H₂O vapor is generated.

The insulating layer may be conformally and thinly formed in the gaps between the structures or in the trenches on semiconductor substrate. The thickness of the insulating layer may be adjusted according to depths or an aspect ratio of the gaps or the trenches.

An SOG layer, coated by an SOG solution, may be on the insulating layer (operation S30). The SOG solution for coating the SOG layer may be a solution obtained by dissolving polysilazane, which is an inorganic polymer, in an organic solvent. The gaps or the trenches covered with the insulating layer may be filled with the SOG layer.

Then, a component of an organic solvent in the SOG layer may first be removed by baking the resultant structure at about 300° C. to about 400° C. (operation S40). The baking of the resultant structure may be performed under an atmosphere of O₂ or H₂O; however, the present embodiment is not limited thereto, and thus, the baking of the resultant structure may be performed under an atmosphere that does not contain O₂ or H₂O. Organic solvent components of the insulating layer may be taken off during the baking. The baking may be selectively performed under an atmosphere that does not contain O₂.

Curing may be performed to oxidize the coated SOG layer (operation S50). Curing may be performed under an atmosphere in which an oxygen source is supplied. For example, curing may be performed through wet-annealing under an atmosphere of H₂O. An oxygen source in an atmosphere, e.g., H₂O, may be used as a source for oxidizing the SOG layer. Also, oxygen necessary for curing the SOG layer may be provided by the insulating layer, and thus, curing may also be performed under an atmosphere that does not contain an oxygen source. For example, curing may be performed through annealing under an atmosphere of N₂.

Curing may be performed at about 700° C. to 1,000° C. Through curing, chemical elements, e.g., hydrogen and nitrogen, in the SOG layer may be replaced with oxygen to change the SOG layer into a silicon oxide layer (referred to herein as an SOG oxide layer) (operation S60).

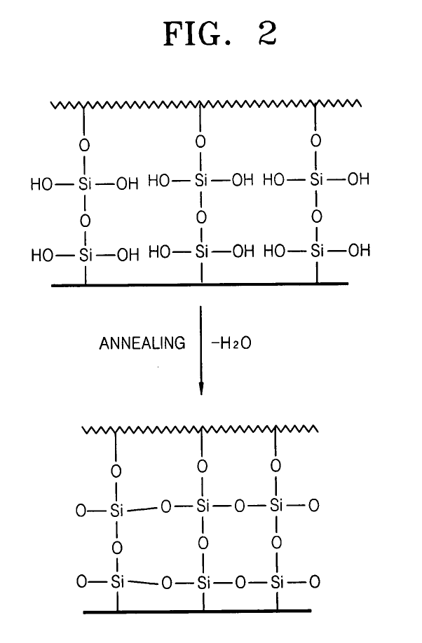

FIG. 2 illustrates H₂O escaping from an insulating layer, e.g., an OH-rich silicon oxide layer, during annealing for curing an SOG layer. The H₂O that escapes from the OH-rich silicon oxide layer may be used as an oxygen source for oxidizing the SOG layer. Referring to FIG. 2, since silicon is bonded with many OH groups in the OH-rich silicon oxide layer, the OH-rich silicon oxide layer may not be dense, and thus, H₂O may likely to escape from the OH-rich silicon oxide layer. After H₂O escapes from the OH-rich silicon oxide layer, the total number of Si—O—Si bonds may be increased in the OH-rich silicon oxide layer, thereby obtaining a silicon oxide layer with a good texture, e.g., a denser and evenly formed silicon oxide layer.

Under an annealing atmosphere, an oxygen source may not be sufficiently supplied to the bottom surfaces of, or inner surfaces of, gaps or trenches to oxidize an SOG layer. Thus, if the oxygen source is supplied only under the annealing atmosphere, the SOG layer on the bottom surfaces of, or inner surfaces of, the gaps or the trenches may not be appropriately cured. Curing failures may locally occur at the bottoms of or the inner surfaces of gaps or trenches. In this case, the SOG layer may not be appropriately oxidized, thus, characteristics of the SOG layer including a tolerance to wet chemicals may be degraded. Portions of the SOG oxide layer, e.g., on the bottom surfaces of, or the inner surfaces of, the gaps or the trenches, in which curing failures occur, may be difficult to oxidize, and thus, may become porous. However, if an OH-rich silicon oxide layer is formed below the SOG layer, an oxygen source, e.g., H₂O, may be sufficiently supplied from the OH-rich silicon oxide layer to the portions of the SOG layer covering the bottom surfaces of, or the inner surfaces of, the gaps or the trenches, thereby obtaining an evenly formed SOG oxide layer without curing failures.

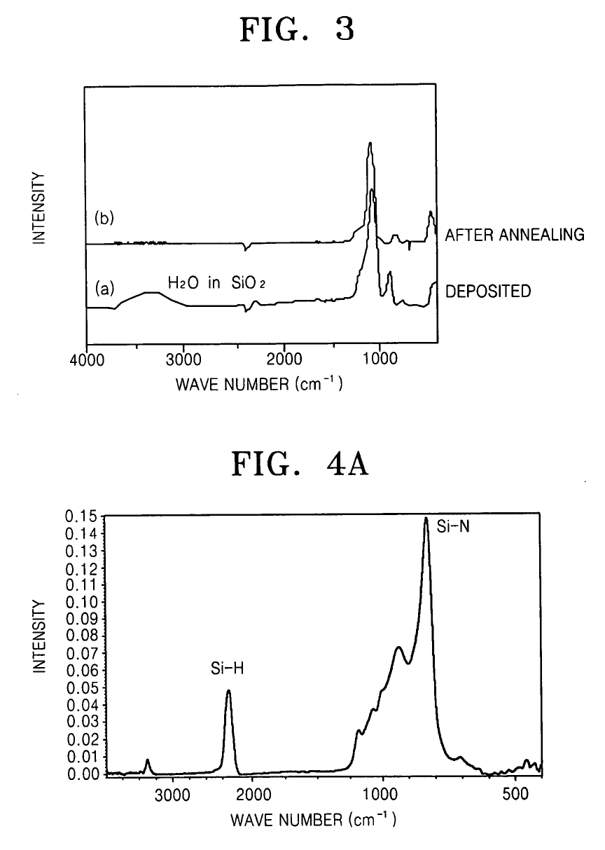

FIG. 3 illustrates FT-IR spectra of an OH-rich silicon oxide layer. Spectrum (a) of FIG. 3 denotes an FT-IR spectrum of the OH-rich silicon oxide layer when the OH-rich silicon oxide layer is deposited but not annealed. Spectrum (b) of FIG. 3 denotes an FT-IR spectrum of the OH-rich silicon oxide layer when the OH-rich silicon oxide layer is deposited and then annealed. In both the spectra (a) and (b), a large and sharp peak corresponding to SiO₂ appears at about wave number of 1,100 cm⁻¹. A small and broad peak corresponding to —OH appears at about wave number of 3,300 cm⁻¹ in the spectrum (a), but does not appear in the spectrum (b). That is, the spectrum (a) shows that many OH groups are included in the OH-rich silicon oxide layer before annealing, and the spectrum (b) shows that the OH groups have escaped from the OH-rich silicon oxide layer, and thus, the OH-rich silicon oxide layer may become a general silicon oxide layer after annealing. The OH groups escaping in the form of H₂O from the OH-rich silicon oxide layer may be used to oxidize the SOG layer.

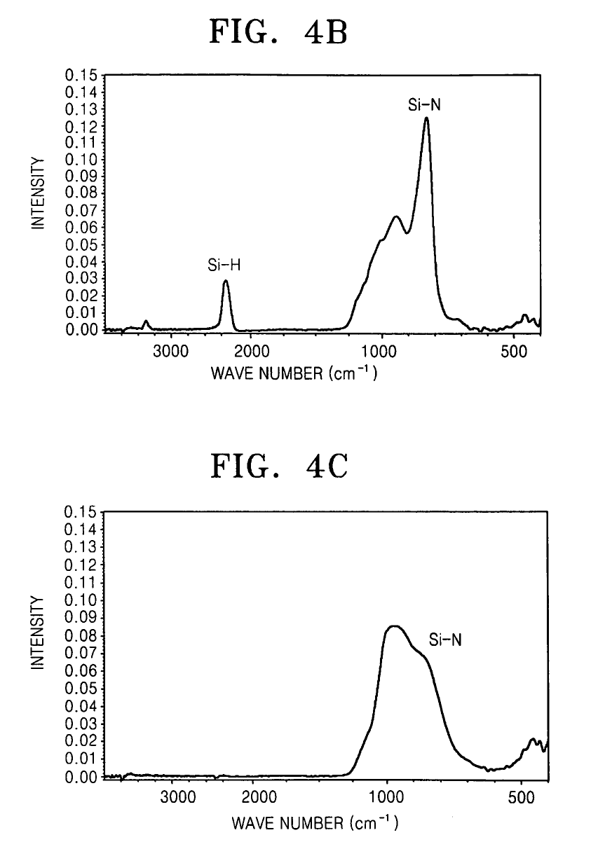

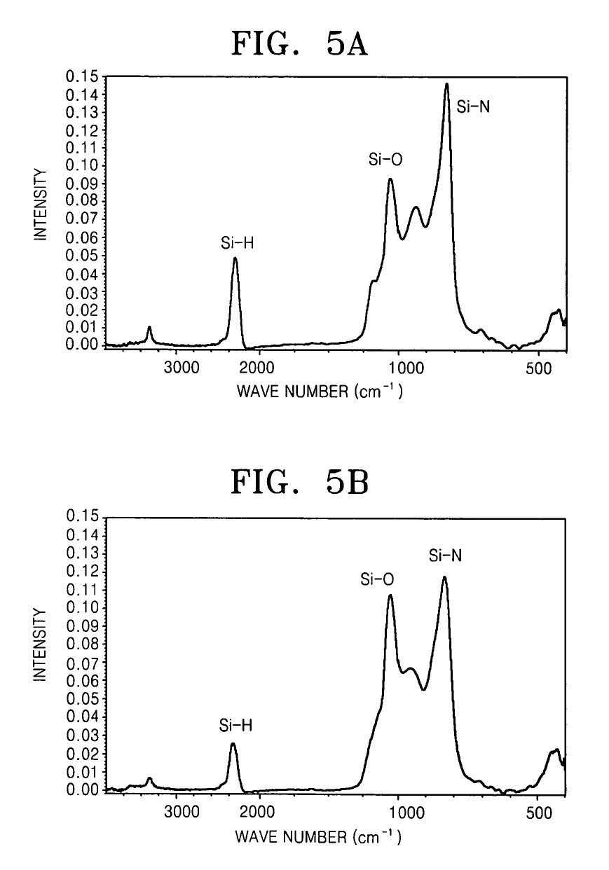

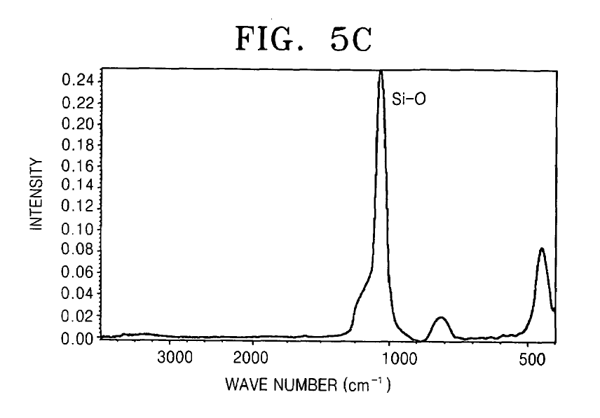

FIG. 4A illustrates an FT-IR spectrum when an SOG layer is deposited. FIG. 4B illustrates an FT-IR spectrum when the SOG layer is baked at 400° C. under an atmosphere of O₂. FIG. 4C illustrates an FT-IR spectrum when the SOG layer is baked at 400° C. under the atmosphere of O₂ and then annealed at 800° C. under an atmosphere of N₂. FIG. 5A illustrates an FT-IR spectrum when an SOG layer is deposited on a silicon oxide layer with many OH groups. FIG. 5B illustrates an FT-IR spectrum when the deposited SOG layer is baked at 400° C. under the atmosphere of O₂. FIG. 5C illustrates an FT-IR spectrum when the OH-rich silicon oxide layer or the SOG layer is baked at 400° C. under the atmosphere of O₂ and then annealed at 800° C. under an atmosphere of N₂.

Referring to FIG. 4C, when only the SOG layer is formed, even if the SOG layer is baked at 400° C. under the atmosphere of O₂ and then annealed at 800° C. under the atmosphere of N₂, a wide peak corresponding to Si—N bonds appears at a wave number of about 850 cm⁻¹. However, referring to FIG. 5C, when an SOG layer is formed on an OH-rich silicon oxide layer, if the SOG layer is baked at 400° C. under the atmosphere of O₂ and then annealed at 800° C. under the atmosphere of N₂, no peak corresponding to Si—N bonds appears at a wave number of about 850 cm⁻¹. Instead, a sharp peak corresponding to Si—O bonds appears at a wave number of about 1,100 cm⁻¹.

The spectra of FIGS. 4A through 4C and FIGS. 5A through 5C show that the SOG layer may not be appropriately oxidized even if the SOG layer is baked under the atmosphere of O₂ and then annealed under the atmosphere of N₂ when only an SOG layer is formed. In contrast, when an SOG layer is deposited on an OH-rich silicon oxide layer, the SOG layer is appropriately oxidized if the SOG layer is baked under the atmosphere of O₂ and is then annealed under the atmosphere of N₂. This is because the SOG layer may be oxidized to become an SOG oxide layer even under the atmosphere of N₂ since a sufficient oxygen source may be supplied from the OH-rich silicon oxide layer to the SOG layer.

As described above, an SOG layer deposited on an OH-rich silicon oxide layer may be cured to become an SOG oxide layer having a high density and an even texture. Because the SOG oxide layer may have a tolerance to wet chemicals, the SOG oxide layer may prevent bottom surfaces of, or the inner surfaces of, gaps or trenches from being damaged in a cleaning process or a wet etching process.

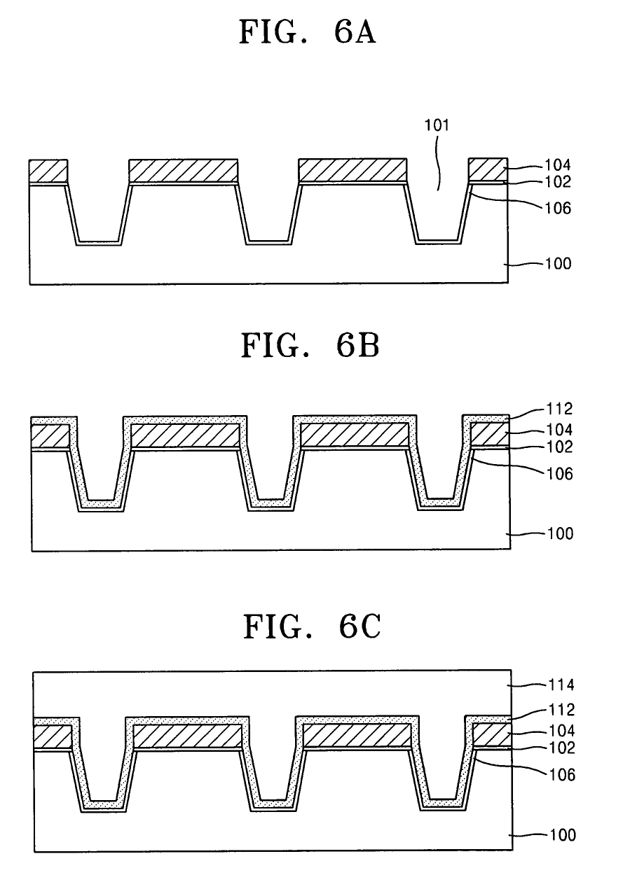

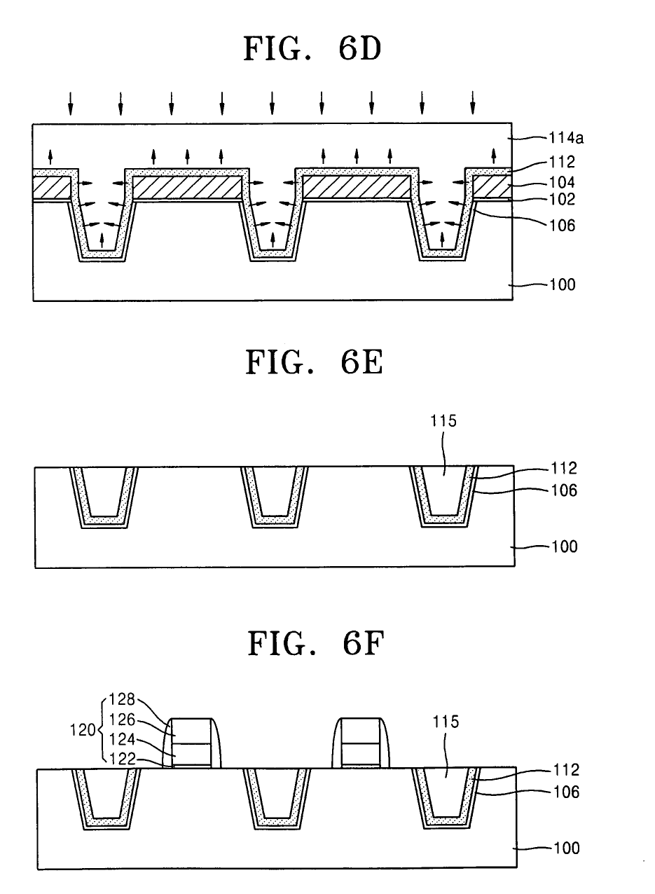

FIGS. 6A through 6F illustrate cross-sectional views of stages in a method of forming a semiconductor device according to an embodiment.

Referring to FIG. 6A, a pad oxide layer 102 and a mask nitride layer 104 may be formed on a semiconductor substrate 100. A plurality of trenches 101 for forming a device isolation layer may be formed on the semiconductor substrate 100 by etching the semiconductor substrate 100 using the mask nitride layer 104 as a mask. Then, a linear silicon nitride layer 106 may be formed along sidewalls and a bottom surface of each of the trenches 101. The linear silicon nitride layer 106 may not be formed on sidewalls of the mask nitride layer 104 and the pad oxide layer 102. The linear silicon nitride layer 106 may be formed after forming a linear silicon oxide layer (not shown) in the trench 101.

Referring to FIG. 6B, an insulating layer 112, e.g., an OH-rich silicon oxide layer, may be formed on the linear silicon nitride layer 106. The insulating layer 112 may supply oxygen. The insulating layer 112 may be formed on an inner surface of the linear silicon nitride layer 106. The insulating layer 112 may be also formed on top and sidewalls of the mask nitride layer 104 and sidewalls of the pad oxide layer 102. The insulating layer 112 may be obtained at about 100° C. to about 300° C. according to an ALD, a PECVD or an HDP method by using H₂O vapor as an oxygen source. The thickness of the insulating layer 112 may be controlled according to a width and height of each of the trenches 101. The thickness of the insulating layer 112 may be about several tens of Å to about several hundreds of Å.

Referring to FIG. 6C, an SOG layer 114 may be formed on the insulating layer 112. The SOG layer 114 may be formed of, e.g., a polysilazane-based material. The SOG layer 114 may be formed according to a spin-coating method. The SOG layer 114 may be baked at about 300° C. to about 400° C. The baking of the SOG layer 114 may be performed under an atmosphere of O₂ or H₂O, or in an oxygen-free atmosphere. An organic solvent may be removed from the SOG layer 114 through the baking of the SOG layer 114.

Referring to FIG. 6D, the SOG layer 114 may be cured to obtain an SOG oxide layer 114a. Curing of the SOG layer 114 may be performed under an atmosphere of oxygen, e.g., through wet-annealing supplying H₂O. Alternatively, curing of the SOG layer 114 may be performed under an atmosphere that does not supply oxygen, e.g., under an atmosphere of N₂. The annealing may be performed at about 700° C. to about 1,000° C.

The atmospheric oxygen source at the top of the SOG layer 114 may not be supplied to the bottom portions of SOG layer 114, e.g., the bottoms or along the inner sidewalls of the trenches 101. However, in the bottom of the SOG layer 114, e.g., the bottoms or along the inner sidewalls of the trenches 101, oxygen may be sufficiently supplied from the insulating layer 112, thereby changing the SOG layer 114 within the trenches 101 into an evenly formed SOG oxide layer 114a. Further, described above, oxygen may be sufficiently supplied from the insulating layer 112 even under an atmosphere that does not contain an oxygen source, and therefore, the SOG layer 114 may be uniformly cured to form the evenly formed SOG oxide layer 114a.

Referring to FIG. 6E, the SOG oxide layer 114a may be planarized through chemical mechanical polishing (CMP) by using the mask nitride layer 104 as a stop layer. Then, the mask nitride layer 104 may be removed through wet etching using a phosphate solution, and a cleaning process may be performed on the resultant structure to obtain a device isolation layer 115. The device isolation layer 115 may fill the trenches 101. In filling the trenches 101, the insulating layer 112 may be between the device isolation layer 115 and the inner sidewalls of the trenches 101. Even if the device isolation layer 115 is exposed through the wet etching using the phosphate solution and the cleaning process, since the device isolation layer 115 at the inner sidewalls of the trenches 101 may be sufficiently oxidized, it may have a tolerance to etching. Accordingly, the device isolation layer 115 at the inner sidewalls of the trenches 101 may not be damaged.

Referring to FIG. 6F, a plurality of gate electrodes 120 may be formed on the semiconductor substrate 100 having the device isolation layer 115. For example, the gate electrodes 120 may each be obtained by patterning a gate insulating layer 122, a conductive layer 124 for the gate electrodes 120, and a hard mask layer 126 formed on the semiconductor substrate 100 and forming a gate spacer 128 along sidewalls of the patterned structure. In a flash memory device, each of the gate electrodes 120 may be either a stacked structure including, from bottom to top, a tunneling insulating layer, a charge trapping layer, a blocking insulating layer, and a control gate, or a stacked structure including, from bottom to top, a tunneling insulating layer, a floating gate, a gate interlayer dielectric layer, and a control gate. Thus, each of the gate electrodes 120 may have various structures according to the type of the semiconductor device.

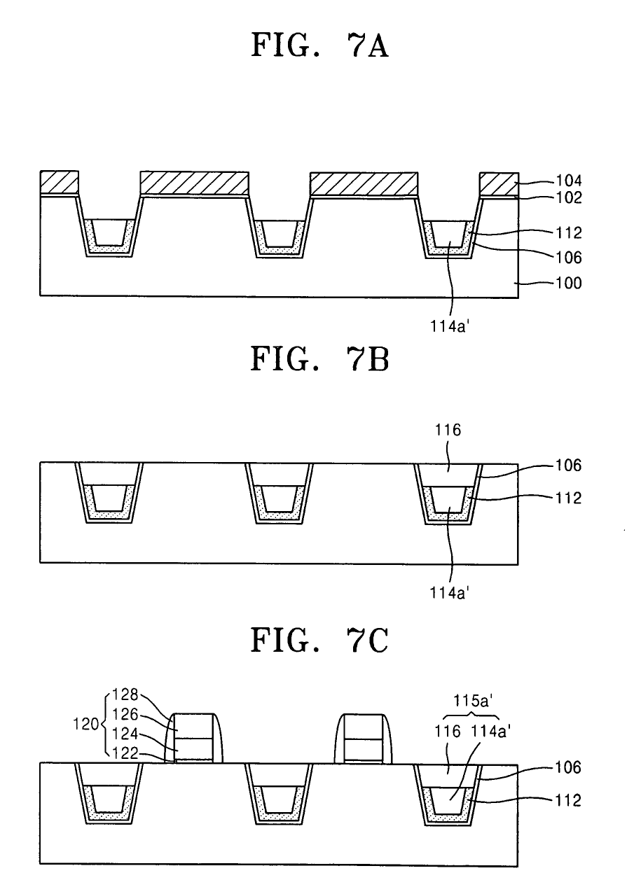

FIGS. 7A through 7C illustrate cross-sectional views of stages in a method of forming a semiconductor device according to another embodiment. In the current embodiment, the operations of forming and baking the SOG layer 114 are the same as described above with reference to FIGS. 6A through 6C. Thus, a detailed description of the same components as those of FIGS. 6A to 6C will be omitted.

Referring to FIG. 7A, the SOG layer within a plurality of trenches 101 may be recessed to a predetermined depth from a top surface of a semiconductor substrate 100, e.g., may not fill the trenches 101 completely. For example, some portions of the inner sidewalls of the trenches 101 may be exposed. The SOG layer may be recessed through dry etching or wet etching. A portion of the insulating layer 112, e.g., portions on top and sidewalls of the mask nitride layer 104, on sidewalls of the pad oxide layer 102 and on upper sidewalls of the trench 101 may also be recessed through dry etching or wet etching. For example, the portion of the insulating layer 112 in the trenches corresponds to the SOG layer. In other words, the exposed sidewalls of the trenches 101 may not have the insulating layer 112 as well as the SOG layer.

The recessed SOG layer may be cured at about 700° C. to about 1,000° C. under an annealing atmosphere that contains an oxygen source, e.g., through wet-annealing supplying H₂O, or under an annealing atmosphere that does not contain an oxygen source, e.g., under an annealing atmosphere of N₂. The insulating layer 112 may then supply an oxygen source to the SOG layer from bottoms of or the inner sidewalls of the trenches 101, and thus, the SOG layer within the trenches 101 may be changed into an evenly formed SOG oxide layer 114a′. If the recessing process is included, the annealing of the recessed SOG layer at about 700° C. to about 1,000° C. may be omitted and the baking process may be replaced with a curing process. The baking process may be performed under an atmosphere of O₂ or H₂O, or under an oxygen-free atmosphere. Organic solvent components of the SOG layer may be taken off during the baking. The baking may be selectively performed under an atmosphere that does not contain O₂.

Referring to FIG. 7B, an upper insulating layer 116 may be formed on the semiconductor substrate 100 to fill up the recesses in the trenches 101, e.g., to fill exposed portions of the trenches 101. The upper insulating layer 116 may be, e.g., a silicon oxide layer, an HDP oxide layer or an O₃-TEOS oxide layer. The upper insulating layer 116 may be denser than that of the SOG oxide layer 114a′, thereby preventing the SOG oxide layer 114a′ from being damaged in a process, e.g., wet etching or a cleaning process.

Subsequently, the upper insulating layer 116 may be planarized through CMP by using the mask nitride layer 104 as a stop layer. Then the mask nitride layer 104 may be removed using a phosphate solution, and a cleaning process may be performed on the resultant structure to obtain a device isolation layer 115a (see FIG. 7C) including the SOG oxide layer 114a′ and the upper insulating layer 116. Referring to FIG. 7C, a process of forming gate structures may be performed as described above with reference to FIG. 6F.

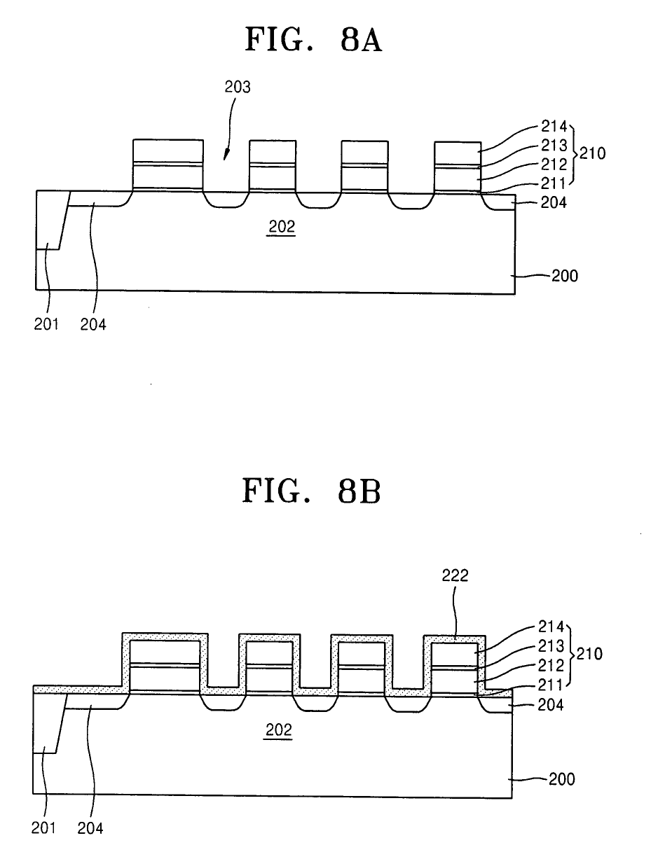

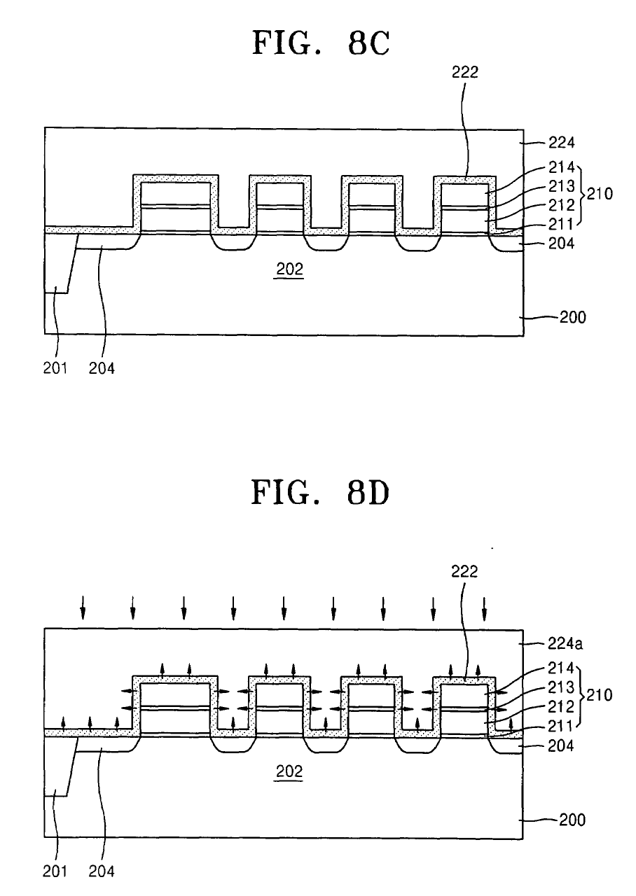

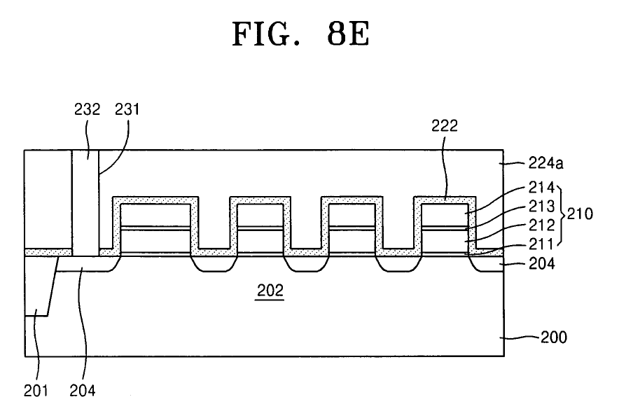

FIGS. 8A through 8D illustrate cross-sectional views of stages in a method of forming a semiconductor device according to another embodiment. Referring to FIG. 8A, a plurality of gate electrodes 210 may be formed on a semiconductor substrate 200 having an active area 202 and a device isolation area 201. The plurality of gate electrodes 210 may be formed in the active area 202 of the semiconductor substrate 200. Each of the gate electrodes 210 may have a stacked structure including, from bottom to top, a gate insulating layer 211, a floating gate 212, a gate interlayer dielectric layer 213, and a control gate 214. Gap 203 may be formed between adjacent gate electrodes 210. A source/drain region 204 may be formed on both sides of each of the gate electrodes 210 in the active area 202. The source/drain region 204 may be formed underneath the gate electrode on both sides, respectively. The gaps 203 may correspond, e.g., be on top of, the source/drain region 204 formed on the semiconductor substrate 200.

Referring to FIG. 8B, an insulating layer 222, e.g., an OH-rich silicon oxide layer, may be formed on the semiconductor substrate 200, e.g., including both the device isolation area 201 and on the active area 202 covering inner walls of the gaps 203, and on the gate electrodes 210 covering a top surface of the control gate 214 and sidewalls. The insulating layer 222 may supply an oxygen source. The insulating layer 222 may be formed at about 100° C. to about 300° C. according to an ALD, a PECVD or an HDP method by using H₂O vapor as an oxygen source. The thickness of the insulating layer 222 may be controlled according to a width and a height of each of the gate electrodes 210. The thickness of the insulating layer 222 may be about several tens of Å to about several hundreds of Å. An etch stop layer (not shown) may be formed prior to forming the insulating layer 222. The etch stop layer may be formed of a material, e.g., a silicon nitride, which has an etch selectivity with respect to an SOG oxide layer 225 formed in a subsequent stage.

Referring to FIG. 8C, an SOG layer 224 may be formed on the insulating layer 222. The SOG layer 224 may be formed of, e.g., a polysilazane-based material. The SOG layer 224 may be formed through spin-coating and then may be baked at about 300° C. to about 400° C. The baking of the SOG layer 224 may be performed under an atmosphere of O₂ or H₂O. Since an oxygen source may be supplied from the insulating layer 222, the baking may be selectively performed under an atmosphere that does not contain O₂ or H₂O.

Referring to FIG. 8D, the SOG layer 224 may be cured to form the SOG oxide layer 224a. Curing of the SOG layer 224 may be performed under an atmosphere of oxygen, e.g., through wet-annealing for supplying H₂O. Alternatively, curing of the SOG layer 224 may be performed under an atmosphere that does not supply oxygen, e.g., under an annealing atmosphere of N₂. The annealing may be performed at about 700° C. to about 1,000° C. The insulating layer 222 may then supply an oxygen source to the portions of the SOG layer 224, e.g., at bottoms of or sidewalls of the gaps 203, thereby enabling the portions of the SOG layer 224 within the gaps 203 to change into an evenly formed SOG oxide layer 224a.

Also, the SOG layer 224 or the SOG oxide layer 224a may be planarized before/after baking the SOG layer 224 or before/after annealing the SOG layer 224.

Referring to FIG. 8E, a contact 232 may be formed through the SOG oxide layer 224a to be connected to the source/drain region 204 adjacent to the device isolation area 201. The contact 232 may be obtained by etching the SOG oxide layer 224a and the insulating layer 222 to form a contact hole 231 and then by filling the contact hole 231 with a conductive layer (not shown).

In the current embodiment, the structures of the gate electrodes 210 and the location and structure of the contact 232 may be variously determined according to the type of the semiconductor device.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming an insulating layer of a semiconductor device, the method comprising:
preparing a semiconductor substrate having a plurality of structures and gaps between adjacent structures;
forming an insulating layer for oxygen supply on the semiconductor substrate;
forming an SOG (spin-on-glass) layer on the insulating layer for oxygen supply to fill the gaps; and
curing the SOG layer, wherein the insulating layer for oxygen supply supplies oxygen to the SOG layer during curing of the SOG layer.

2. The method as claimed in claim 1, wherein the SOG layer is directly on the insulating layer for oxygen supply.

3. The method as claimed in claim 2, wherein the insulating layer for oxygen supply includes an OH-rich silicon oxide layer.

4. The method as claimed in claim 3, wherein the OH-rich silicon oxide layer is formed through atomic layer deposition (ALD) or chemical vapor deposition (CVD) using H₂O vapor.

5. The method as claimed in claim 3, wherein the OH-rich silicon oxide layer is formed at about 100° C. to about 300° C.

6. The method as claimed in claim 1, wherein the SOG layer is formed of a polysilazane-based material.

7. The method as claimed in claim 1, further comprising baking the SOG layer after forming the SOG layer and before curing the SOG layer.

8. The method as claimed in claim 1, wherein curing of the SOG layer includes annealing under an atmosphere of H₂O or under an atmosphere that does not contain an oxygen supply gas.

9. The method as claimed in claim 1, wherein the structures include conductive lines.

10. The method as claimed in claim 1, wherein the plurality of structures and the gaps are formed on an active area of the semiconductor substrate, and the gaps include trenches in which a device isolation layer is to be formed.

11. A method of forming a semiconductor device, the method comprising:
forming a plurality of trenches in a semiconductor substrate;
forming an insulating layer for oxygen supply on the semiconductor substrate including the trenches;
forming an SOG (spin-on-glass) layer on the insulating layer for oxygen supply on the semiconductor substrate to fill the trenches with the SOG layer; and
curing the SOG layer, wherein the insulating layer for oxygen supply supplies oxygen to the SOG layer during curing of the SOG layer.

12. The method as claimed in claim 11, wherein the insulating layer for oxygen supply includes an OH-rich silicon oxide layer formed using H₂O vapor.

13. The method as claimed in claim 11, wherein the SOG layer is directly on the insulating layer for oxygen supply.

14. The method as claimed in claim 11, further comprising planarizing the cured SOG layer to form a device isolation layer.

15. A method of forming a semiconductor device, the method comprising:
forming a plurality of trenches in a semiconductor substrate;
forming an insulating layer for oxygen supply on the semiconductor substrate including the trenches;
forming an SOG (spin-on-glass) layer on the insulating layer for oxygen supply on the semiconductor substrate to fill the trenches with the SOG layer;
recessing parts of the SOG layer in the trenches;
curing the SOG layer on the semiconductor substrate; and
forming an upper insulating layer on the SOG layer to fill the trenches, wherein the insulating layer for oxygen supply supplies oxygen to the SOG layer during curing of the SOG layer.

16. The method as claimed in claim 15, wherein the insulating layer for oxygen supply includes an OH-rich silicon oxide layer formed using H₂O vapor.

17. The method as claimed in claim 15, wherein the SOG layer is directly on the insulating layer for oxygen supply.

18. The method as claimed in claim 15, wherein the upper insulating layer includes one of a HDP (high-density plasma) silicon oxide layer and an O₃-TEOS silicon oxide layer.

19. The method as claimed in claim 15, further comprising planarizing the cured SOG layer to form a device isolation layer.

20. The method as claimed in claim 18, further comprising forming gate insulating layers and gate electrodes on the semiconductor substrate.
